(19) United States
(12) Patent Application Publication
(10) Pub. No.: US 2018/0358390 A1
(43) Pub. Date: Dec. 13, 2018

(54) DIELECTRIC CAPACITOR

(71) Applicant: CSMC TECHNOLOGIES FAB2 CO., LTD., Wuxi New District (CN)

(72) Inventors: Xinxin LIU, Wuxi New District (CN); Xiaodong HE, Wuxi New District (CN)

(21) Appl. No.: 15/766,428

(22) PCT Filed: Aug. 24, 2016
(86) PCT No.: PCT/CN2016/096582

§ 371 Date: Apr. 6, 2018

(30) Foreign Application Priority Data
Oct. 8, 2015 (CN) 201510648134.9

(51) Int. Cl. H01L 27/13; H01L 23/64; H01L 49/02; H01L 27/12

(52) U.S. Cl. CPC H01L 27/13; H01L 27/1203; H01L 28/40; H01L 23/642

(57) ABSTRACT

A dielectric capacitor includes: a bottom silicon layer (102); a buried oxide layer (104) formed on a surface of the bottom silicon layer (102); a top silicon layer (106) formed on a surface of the buried oxide layer (104); an interlayer dielectric layer (108) formed on a surface of the top silicon layer (106); a lower plate (110), an insulation layer (112), and an upper plate (114) sequentially formed on the interlayer dielectric layer (108) and forming the main portion of the dielectric capacitor; a shallow trench isolation structure (116) formed on the top silicon layer (106) and configured to isolate an active region; and a deep trench isolation structure (118) formed below the lower plate (110) and passing through the top silicon layer (106) to be connected to the buried oxide layer (104).

### TECHNICAL FIELD

The present disclosure relates to the technical field of semiconductors, and particularly relates to a dielectric capacitor.

### BACKGROUND

In the production of semiconductors, a dielectric capacitor based on Silicon-On-Insulator (SOI) processes is widely applied in analog radio-frequency circuits. Conventional SOI-based dielectric capacitor has parasitic capacitances on the upper plate, the lower plate, and the substrate. The parasitic capacitances can bring some unknown effects on circuit design, thus the circuit performance does not meet the expected requirements.

### SUMMARY

Accordingly, it is necessary to provide a dielectric capacitor that can reduce the parasitic capacitance effect.

A dielectric capacitor includes a bottom silicon layer; a buried oxide layer formed on a surface of the bottom silicon layer; a top silicon layer formed on a surface of the buried oxide layer; an interlayer dielectric layer formed on a surface of the top silicon layer; a lower plate, an insulation layer, and an upper plate sequentially formed on the interlayer dielectric layer; and forming a main portion of the dielectric capacitor; a shallow trench isolation structure formed on the top silicon layer and configured to isolate an active region; and a deep trench isolation structure formed beneath the lower plate and penetrating the top silicon layer to be connected to the buried oxide layer.

According to the aforementioned dielectric capacitor, the deep trench isolation structure is formed beneath the plates and connected to the buried oxide layer, so as to achieve a good isolation of the device. The exchange of charges between the plates and the top silicon layer (i.e., the substrate of the dielectric capacitor) is reduced, thus it becomes very difficult to exchange charges between the plates and the substrate, and the parasitic capacitances between the plates and the substrate are reduced.

### BRIEF DESCRIPTION OF THE DRAWINGS

To illustrate the technical solutions according to the embodiments of the present disclosure or in the prior art more clearly, the accompanying drawings for describing the embodiments or the prior art are introduced briefly in the following. Apparently, the accompanying drawings in the following description are only some embodiments of the present disclosure, and persons of ordinary skill in the art can derive other drawings from the accompanying drawings without creative efforts.

FIG. 1 is a cross-sectional view of a dielectric capacitor according to an embodiment.

### DETAILED DESCRIPTION OF THE EMBODIMENTS

Embodiments of the present disclosure are described more fully hereinafter with reference to the accompanying drawings. A preferred embodiment is described in the accompanying drawings. The various embodiments of the invention may, however, be embodied in many different forms and should not be construed as limited to the embodiments set forth herein. Rather, these embodiments are provided so that this disclosure will be thorough and complete, and will fully convey the scope of the invention to those skilled in the art.

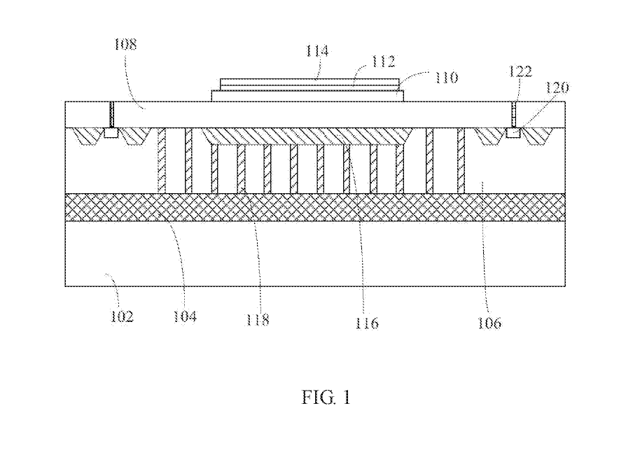

FIG. 1 is a cross-sectional view of a dielectric capacitor according to an embodiment. The dielectric capacitor is based on SOI processes, and the parasitic capacitances between the plates and the substrate are relatively small. Referring to FIG. 1, the dielectric capacitor includes a bottom silicon layer 102, a buried oxide layer 104, a top silicon layer 106, an interlayer dielectric layer 108, a lower plate 110, an insulation layer 112, an upper plate 114, a shallow trench isolation structure 116, a deep trench isolation structure 118, and a substrate lead-out area 120.

In order from bottom to top, the dielectric capacitor sequentially includes the bottom silicon layer 102, the buried oxide layer 104, the top silicon layer 106, the interlayer dielectric layer 108, the lower plate 110, the insulation layer 112, and the upper plate 114. The bottom silicon layer (Sub) 102 can be made of silicon, silicon carbide, gallium arsenide, indium phosphide, or the like. The buried oxide layer (BOX) 104 and the top silicon layer (Bulk) 106 are sequentially formed on the surface of the bottom silicon layer 102, so as to form a SOI structure. In the illustrated embodiment, the top silicon layer 106 serves as a substrate of the dielectric capacitor, and the substrates mentioned hereinafter is referred to the top silicon layer 106. The interlayer dielectric layer (ILD) 108 is formed on the surface of the top silicon layer 106. The interlayer dielectric layer 108 can also be referred as the insulation layer, and is configured to implement the isolation between the lower plate 110 and the top silicon layer 106. The interlayer dielectric layer 108 is made of a nitrite of silicon, such as silicon nitride. The lower plate 110, the insulation layer 112, and the upper plate 114 are sequentially formed on the surface of the interlayer dielectric layer 108 and cooperatively form a main portion of the dielectric capacitor. Both of the upper plate 114 and the lower plate 110 can be metal or polysilicon. In other words, the formed dielectric capacitor can be a poly-insulator-poly (PIP) capacitor, a metal-insulator-metal (MIM) capacitor, or a metal-insulator-poly capacitor. An example of the SOI-based dielectric capacitor according to the embodiment is a MIM capacitor. The shallow trench isolation structure (STI) 116 is formed on the top silicon layer 106 and configured to isolate an active region.

The deep trench isolation structure (trench) 118 is formed beneath the lower plate 110, and the deep trench isolation structure 118 penetrates the top silicon layer 106 and is connected to the buried oxide layer 104. Since the dielectric filled in the deep trench isolation structure 118 is oxide of silicon, the charges between the upper plate 114, the lower plate 110, and the substrate needs to pass layers of oxide layer to exchange, therefore the difficulty of the exchange of charges is increased, the parasitic capacitances between the plates and the substrate are reduced, and the dielectric capacitor can meet the requirements of circuit design. In the illustrated embodiment, a distributing area of the deep trench isolation structures 118 in the top silicon layer 106 is greater than an area of the top silicon layer covered by the lower plate, so as to sufficiently prevent the exchange of charges between the plates and substrate and to reduce the parasitic capacitance effect. A plurality of deep trench isolation structures 118 are provided, and they are spaced apart and distributed in the top silicon layer 106 beneath the lower plate 110. A trench width of the deep trench isolation structures 118 and an interval between the trenches can be configured according to different rules of process design. Taking the 0.18 μm SOI structure according to the illustrated embodiment as an example, the trench width can be ranging from 0.5 μm to 0.7 μm, and the interval can be ranging from 1 μm to 2 μm. In one embodiment, the trench width can be 0.6 μm, and the interval is 1 μm, thus the deep trench isolation structures 118 are distributed as densely as possible under the lower plate 110, so as to increase the difficulty of the exchange of charges between the plates and the substrate. In the illustrated embodiment, a part of the shallow trench isolation structure 116 is located beneath the lower plate 110. Therefore, the deep trench isolation structure 118 beneath the lower plate 110 is connected to the shallow trench isolation 116 structure and the buried oxide layer 104, respectively. In the illustrated embodiment, the shallow trench isolation 116, the deep trench isolation structure 118, and the buried oxide layer 104 are made of an oxide of nitrite. The substrate lead-out area (Bulk lead-out) 120 is formed on the top silicon layer 106 and is located around the main portion of the dielectric capacitor. The substrate lead-out area 120 is connected to an external circuit via a metal contact hole 122 defined in the interlayer dielectric layer 108, so as to lead out a substrate potential, and to control the substrate potential.

According to the aforementioned dielectric capacitor, the deep trench isolation structure 118 formed beneath the plates and connected to the buried oxide layer 104, so as to achieve a good isolation of the device. The exchange of charges between the plates and the substrate is reduced, thus it becomes very difficult to exchange charges between the plates and the substrate, and the parasitic capacitances between the plates and the substrate are reduced.

The technical features of the embodiments described above can be arbitrarily combined. In order to make the description succinct, there is no describing of all possible combinations of the various technical features in the foregoing embodiments. It should be noted that there is no contradiction in the combination of these technical features which should be considered as the scope of the description.

Although the present disclosure is illustrated and described herein with reference to specific embodiments, the present disclosure is not intended to be limited to the details shown. It is to be noted that, various modifications may be made in the details within the scope and range of equivalents of the claims and without departing from the present disclosure. Therefore, the protection scope of the present disclosure shall be subject to the protection scope of the claims.

What is claimed is:

1. A dielectric capacitor, comprising:
a bottom silicon layer;
a buried oxide layer formed on a surface of the bottom silicon layer;
a top silicon layer formed on a surface of the buried oxide layer;
an interlayer dielectric layer formed on a surface of the top silicon layer;
a lower plate, an insulation layer, and an upper plate sequentially formed on the interlayer dielectric layer and forming; wherein the lower plate, the insulation layer, and the upper plate form a main portion of the dielectric capacitor;
a shallow trench isolation structure formed on the top silicon layer and configured to isolate an active region; and
a deep trench isolation structure formed beneath the lower plate, wherein the deep trench isolation structure penetrates the top silicon layer and is connected to the buried oxide layer.

2. The dielectric capacitor according to claim 1, wherein the number of the deep trench isolation structure is plural, and the plurality of spaced apart deep trench isolation structures are distributed in the top silicon layer beneath the lower plate.

3. The dielectric capacitor according to claim 2, wherein the deep trench isolation structure has a trench width ranging from 0.5 μm to 0.7 μm.

4. The dielectric capacitor according to claim 3, wherein the trench width of the deep trench isolation structure is 0.6 μm.

5. The dielectric capacitor according to claim 2, wherein an interval between the deep trench isolation structures is from 1 μm to 2 μm.

6. The dielectric capacitor according to claim 2, wherein a distributing area of the deep trench isolation structures in the top silicon layer is greater than an area of the top silicon layer covered by the lower plate.

7. The dielectric capacitor according to claim 1, wherein a part of the shallow trench isolation structure is located beneath the lower plate; the deep trench isolation structure beneath the lower plate is connected to the shallow trench isolation structure and the buried oxide layer, respectively.

8. The dielectric capacitor according to claim 1, wherein the shallow trench isolation structure and the shallow trench isolation structure are both made of oxide of silicon.

9. The dielectric capacitor according to claim 1, wherein the upper plate and the lower plate are both made of polysilicon or metal.

10. The dielectric capacitor according to claim 1, further comprising a substrate lead-out area formed on the top silicon layer and located around the main part of the dielectric capacitor; wherein the interlayer dielectric layer further defines a metal contact hole located above the substrate lead-out area; and the substrate lead-out area is connected to an external circuit via the metal contact hole.

11. The dielectric capacitor according to claim 1, wherein the bottom silicon layer is made of silicon, silicon carbide, gallium arsenide, or indium phosphide.
